(19) United States
(12) Patent Application Publication
(10) Pub. No.: US 2009/0022982 A1
(43) Pub. Date: Jan. 22, 2009

(54) Electronic Device, Method of Manufacture of Same and Sputtering Target

(75) Inventors: Eugene Y. Ivanov, Grove City, OH (US); Timothy J. Wiemels, Powell, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: Tosoh SMD, Inc., Grove City, OH (US)

(21) Appl. No.: 12/223,500

(22) PCT Filed: Feb. 21, 2007
(86) PCT No.: PCT/US2007/004490

§ 371 Date: Jul. 31, 2008

Related U.S. Application Data
(60) Provisional application No. 60/779,704, filed on Mar. 6, 2006.

(51) Int. Cl. B32B 15/00; C23C 14/34; B32B 5/00; B23P 17/00

(52) U.S. Cl. 428/336; 204/192.1; 204/298.13; 428/469; 428/472; 29/592.1

(57) ABSTRACT

An electronic device having a first electrode including a metal oxide and a second electrode including an aluminum alloy film and manufacturing technology therefor. The second electrode is directly contacted and electrically connected to the first electrode, wherein, in the contact interface between the aluminum alloy film and said first electrode, at least a part of alloy components constituting the aluminum alloy film exist as a precipitate extending across the contact interface to contact the metal oxide to the aluminum alloy film by the precipitate. This construction enables direct contact between the aluminum alloy film and the electrode consisting of a metallic oxide and allows for elimination of a barrier metal in such an electronic device.

### REFERENCE TO RELATED APPLICATION

This application claims the priority benefit of U.S. Provisional Patent Application Ser. No. 60/779,704 filed Mar. 6, 2006.

### BACKGROUND OF THE INVENTION

1. Field of the Invention

This invention relates to an electronic device in a thin film form, the method of its manufacture, and a sputtering target. Specifically the invention relates to a novel display device comprising, as its constituents, pixel electrodes used in active and passive matrix type flat panel displays such as semiconductor displays and liquid crystal displays, reflective films, optical components etc-, and aluminum alloy film; the method of its manufacture; and the sputtering target.

2. Description Of The Related Art

The active matrix type liquid crystal display uses thin film transistors (TFT) as switching elements, and is composed of a TFT array substrate equipped with a wiring section of pixel electrodes, scan lines, signal conductors, etc., an opposed substrate equipped with a common electrode that is disposed in opposition to the TFT array substrate with a predetermined spacing, and a liquid crystal layer that is filled between the TFT array substrate and the opposed substrate. For the pixel electrodes, an indium tin oxide (ITO) film with about 10 wt % tin oxide (SnO) contained in indium oxide (In₂O₃) and the like is used.

Moreover, regarding the signal conductors of the wiring section that are connected to these pixel electrode electrically, in order that pure aluminum or an aluminum alloy, such as Al—Nd, shall not come in direct contact with the pixel electrodes, a multilayer film made of a high melting point metal, such as Mo, Cr, Ti, and W, is made to exist between them as a barrier metal. However, recently, trials where these high melting point metals are eliminated and the pixel electrode is brought into direct connection with the signal conductor are being advanced.

For example, according to JP-A No. 337976/1999, it is described that if a pixel electrode made of an ITO film with about 10 wt % zinc oxide contained in indium oxide is used, direct contact with signal conductors becomes possible. U.S. Pat. No. 6,218,206 discloses a method of performing surface treatment on a drain electrode by plasma processing or ion implantation, and U.S. Pat. No. 6,252,247 discloses a method of forming a multilayer film by depositing a second phase containing impurities, such as N, O, Si, and C, on a first layer of gate, source, and drain electrodes. It was made clear that adoption of these methods makes it possible to maintain contact resistance with the pixel electrode to a low level even if the high melting point metal is eliminated.

The reason for disposing a barrier metal in-between in the conventional technology is that, if aluminum or aluminum alloy wiring that constitutes signal conductors is brought into direct contact with the pixel electrode, the contact resistance will increase and display quality of a screen will deteriorate. This is because aluminum is very easy to oxidize and the surface thereof is easily oxidized in the air and because the pixel electrode is a metal oxide and hence aluminum is oxidized by oxygen generated at the time of film deposition and oxygen added at the time of film deposition to form an aluminum oxide layer on the surface thereof. Then, if an insulating material layer is formed in the contact interface between the signal conductors and the pixel electrode in this way, the contact resistance between the signal conductors and the pixel electrode will increase and the display quality of a screen will deteriorate.

On the other hand, although the barrier metal has originally an action of preventing surface oxidization of the aluminum alloy and improving contact between the aluminum alloy film and the pixel electrode, a barrier metal forming process becomes indispensable to obtain the conventional structure wiring such that a barrier metal is disposed between the contact interface; therefore, a deposition chamber for forming a barrier metal must be provided redundantly in addition to a depositing sputtering apparatus required for the formation of the gate electrode, the source electrode, and the drain electrode. However, as the cost of a liquid crystal panel etc. keeps to be reduced by mass production, it has become difficult to neglect the increase in the manufacturing cost and the decrease in productivity accompanying the formation of a barrier metal.

Due to such circumstances, an electrode material and a manufacturing process that enables dispensing of the barrier metals are desired recently. In response to such a demand, U.S. Pat. No. 6,218,206 supplemented one process for performing surface treatment. On the other hand, according to U.S. Pat. No. 6,252,247, deposition of the gate electrode, the source electrode, or the drain electrode can be performed continuously in the same deposition chamber, but increase in the number of steps cannot be avoided. Besides, when the chamber is used continuously, there occurs frequently a phenomenon that films peel off the wall of the chamber due to a difference of thermal expansion coefficient between a film into which impurities have been mixed and a film into which no impurity has been mixed, and consequently the equipment must be halted frequently because of maintenance. Moreover, according to the patent document 1, indium tin oxide (ITO) that is most popular at present must be altered to indium zinc oxide (IZO), which increases material cost.

In order to maintain the display quality of a display device, the electrode material is required to provide low electric resistance and a high level of heat resistance. For example, the properties required to be used as a source and drain electrode material of the amorphous TFT (one of elements of display devices) etc. are an electrical resistivity of 8 μΩ cm or less (preferably, 5 μΩ cm or less) and a heatproof temperature of 300 to 350° C. The properties required to be used as a gate electrode material are an electrical resistivity of 8 μΩ cm or less and a heatproof temperature of 400 to 450° C. Since a current is made to flow always in the source/drain electrodes in order to read a pixel, it is desirable to suppress the electrical resistivity low and hence lessen power consumption of the display device. Moreover, it is necessary to lessen the time constant that is determined as a product of resistance and regulation capacity, so that display quality can be maintained even when the display panel is enlarged. Furthermore, the required heat resistance varies with the structure of a display device, and depends on deposition temperature of an insulating film that is used in post processing after electrode formation, and deposition temperature and heat treatment temperature of semiconductor layers.

It would be desirable to establish a technology that enables commonality of material between the reflective electrode and a TAB connection electrode in an electronic device without the use of a barrier metal and maintain the electric properties capable of realizing low electrical resistivity and low contact resistance compatible with heat resistance. It would also be desirable to manufacture the electronic device without increasing the number of manufacturing steps

### DETAILED DESCRIPTION OF EXEMPLARY EMBODIMENTS

The invention will now be described in the following detailed description wherein preferred embodiments are described in detail to enable practice of the invention. Although the invention is described with reference to these specific preferred embodiments, it will be understood that the invention is not limited to these preferred embodiments. But to the contrary, the invention includes numerous alternatives, modifications and equivalents as will become apparent from consideration of the following detailed description.

An electronic device comprises a first electrode comprising a metal oxide and a second electrode comprising an aluminum alloy film which is directly contacted and electrically connected to the first electrode. As the first electrode used as a constituent of this invention, indium tin oxide and indium zinc oxide are exemplary. Preferably, the aluminum alloy film contains, as its alloy component, at least one element selected from the group consisting of Ca, Sr, Ba, Sm, Sc, Y, La, Mn, Cu, Zn, Ga, In, Sn and Bi in the range of 0.01 to 6 at %.

At the contact interface between the aluminum alloy film and the first electrode, at least a part of the alloy components constituting the aluminum alloy film preferably exists as a precipitate or a concentrated layer. It is preferable that the aluminum alloy film is so formed that a part or all of alloy components forming a solid solution in a non-equilibrium state becomes a precipitate or a concentrated layer and that the electrical resistivity of the aluminum alloy film is suppressed to 8 μΩ cm or less.

It is desirable that the aluminum alloy film containing its alloy component has a Me-concentrated layer whose Me content in a thickness region of 1 to 10 nm from the surface of the film is 10 at % or less. The Me-concentrated layer here means a layer whose Me content is more than that in the inner portion of the aluminum alloy film. Then these aluminum alloy films function effectively as a reflective film or a TAB connection electrode in display devices. Me as used herein means one or more of Ca, Sr, Ba, Sm, Sc, Y, La, Mn, Cu, Zn, Ga, In, Sn and Bi.

The method of manufacture according to this invention is ranked as a useful method for manufacturing the electronic device, and the method comprises the step of forming a precipitate that contains at least a part of the alloy components contained in the aluminum alloy film by heating the aluminum alloy film formed on a substrate at a temperature of 150 to 400° C. The sputtering target of this invention is a useful target material for forming aluminum alloy films as described above, and is characterized in that it contains, as its alloy component, at least one element selected from the group consisting of Ca, Sr, Ba, Sm, Sc, Y, La, Mn, Cu, Zn, Ga, In, Sn and Bi in the range of 0.01 to 6 at %.

The sputtering target of this invention is a useful target material for forming aluminum alloy films as described above, and is manufactured by extrusion method. Further improvement of targets manufacturing process and target performance can be achieved by manufacturing a single piece assembly by extrusion process, where target and backing plate are all extruded in one shape without bonding consisting of the same alloy, or made by a co-extrusion process from Al alloy and another Al alloy for the backing plate base. The invention constructed as described above makes it possible to directly contact between the aluminum alloy film and the electrode, alleviate the manufacturing man-hour and cost by eliminating the barrier metal. And thereby the invention can provide the electronic device and the array substrate having the properties of low-cost and high-performance.

Accordingly an electronic device is provided that comprises a first electrode that includes a metal oxide and a second electrode that includes an aluminum alloy film. The second electrode is directly connected and electrically connected to the first electrode. In the contact interface between the aluminum alloy film and the first electrode, at least a portion of the alloyed components in the aluminum alloy film exist as a precipitate extending across the contact interface to contact the metal oxide to the aluminum alloy film. As indicated above, the alloying elements may be present in an exemplary range of 0.01 to 6 at %. These alloying elements may be selected from the group consisting of Ca, Sr, Ba, Sm, Sc, Y, La, Mn, Cu, Zn, Ga, In, Sn and Bi. In at least one exemplary embodiment, the metal oxide may be either indium tin oxide or indium zinc oxide. In other exemplary embodiment, the aluminum film contains at least Sr as its alloy component. In other exemplary embodiments the alloying component is chosen from Mn, Ni, and Cu.

In other exemplary embodiment, the aluminum alloy film comprising alloy components in precipitate form, has an electrical resistively of not larger than 8 uOhm.cm. In one embodiment the aluminum alloy film comprises Mn in a concentrated layer wherein the Mn content in a thickness region of 1 to 10 nanometers from the surface of the aluminum alloy film is not more than the Mn content inside the aluminum alloy film plus 8 at %. As above indicated, the first electrode may be a pixel electrode and the electronic device may be a display device.

The electronic device may be manufactured via processes including the step of forming a precipitate that contains at least a part of the alloy components contained in the aluminum alloy film via heating of the aluminum alloy film on a substrate at a temperature of about 150 to 400° C. This aluminum alloy film may be formed via a sputtering method. In accordance with the invention, sputtering targets including an aluminum alloy are provided wherein the aluminum alloy includes at least one element selected from the group of Ca, Sr, Ba, Sm, Sc, Y, La, Mn, Cu, Zn, Ga, In, Sn, and Bi in the range of 0.01 to 6 at %. The sputtering target may be formed via an extrusion method in a single piece wherein the single piece comprises both the target and backing plate that are extruded in one shape without bonding therebetween. The target and backing plate both may consist of the same alloy, or, the target and backing plate may be made by a co-extrusion process wherein the target has a first aluminum alloy formulation and another aluminum alloy formulation is utilized for the backing plate base.

While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes can be made without departing from the spirit and scope of this invention.

What is claimed is:

1. An electronic device comprising:
first electrodes including a metal oxide; and
second electrode including an aluminum alloy film, said second electrode being directly contacted and electrically connected to said first electrode, wherein, in the contact interface between said aluminum alloy film and said first electrode, at least a part of alloy components constituting said aluminum alloy film exist as a precipitate extending across the contact interface to contact the metal oxide to the aluminum alloy film by the precipitate.

2. The electronic device according to claim 1, wherein said aluminum alloy film contains at least one element in the range of 0.01 to 6 at % as its alloy component, the element being selected from the group consisting of Ca, Sr, Ba, Sm, Sc, Y, La, Mn, Cu, Zn, Ga, In, Sn and Bi in the range of 0.01 to 6 at %.

3. The electronic device according to claim 1, wherein said metal oxide is indium tin oxide or indium zinc oxide.

4. The electronic device according to claim 2, wherein said aluminum alloy film contains at least Sr as its alloy component.

5. The electronic device according to claim 2, wherein said aluminum alloy film further contains, as its another alloy component, at least one element selected from the group consisting of Mn, Ni, Cu, in the range of 0.01 to 6 at %.

6. The electronic device according to claim 1, wherein said aluminum alloy film in which at least a part of the alloy components exist as a precipitate, and the electrical resistivity of said aluminum alloy film is not larger than 8 uOhm.cm.

7. The electronic device according to claim 4, wherein said aluminum alloy film containing Mn has a Mn-concentrated layer whose Mn content in a thickness region of 1 to 10 nm from the surface of said aluminum alloy film is not more than the Mn content inside the aluminum alloy film plus 8 at %.

8. The electronic device according to claim 1, wherein said first electrode is a pixel electrode and said electronic device is a display device.

9. The method of manufacture of the electronic device according to claim 1, comprising the step of forming a precipitate that contains at least a part of the alloy components contained in said aluminum alloy film by heating said aluminum alloy film formed on a substrate at a temperature of 150 to 400° C.

10. The method of manufacture according to claim 1, wherein said aluminum alloy film is formed by a sputtering method.

11. A sputtering target including an aluminum alloy, said aluminum alloy including at least one element selected from at least one of Ca, Sr, Ba, Sm, Sc, Y, La, Mn, Cu, Zn, Ga, In, Sn and Bi in the range of 0.01 to 6 at %.

12. The sputtering target according to claim 11, manufactured by extrusion method, a single piece assembly manufactured by extrusion process, where target and backing plate are all extruded in one shape without bonding consisting of the same alloy, or made by a co-extrusion process from Al alloy and another Al alloy for the backing plate base.
